(19) United States
(12) Patent Application Publication
(10) Pub. No.: US 2025/0185481 A1
(43) Pub. Date: Jun. 5, 2025

(54) LIGHT EMITTING DISPLAY DEVICE

(71) Applicant: LG Display Co., Ltd., Seoul (KR)

(72) Inventors: Jong Woo PARK, Paju-si (KR); Kwan Soo KIM, Paju-si (KR); Min Jee KIM, Paju-si (KR); Seok Hyun KIM, Paju-si (KR)

(73) Assignee: LG Display Co., Ltd., Seoul (KR)

(21) Appl. No.: 18/962,277

(22) Filed: Nov. 27, 2024

(30) Foreign Application Priority Data
Nov. 30, 2023 (KR) 10-2023-0171630

(51) Int. Cl. H10K 59/131; H10K 59/80; H10K 59/88

(52) U.S. Cl. CPC H10K 59/131; H10K 59/805; H10K 59/88

(57) ABSTRACT

A light emitting display device includes a plurality of sub-pixels that each have a light emitting area. The light emitting display device includes a substrate; a first electrode at each light emitting area on the substrate; an intermediate layer and a second electrode on the first electrode; an auxiliary electrode at a non-light emitting area and spaced apart from the first electrode on the substrate; a bank exposing the light emitting area and the auxiliary electrode; a first partition on the auxiliary electrode and configured to expose a portion of the auxiliary electrode; a first pattern-defining layer on the first partition; and a connection electrode on the auxiliary electrode and electrically connected to the second electrode.

This application claims the benefit of Korean Patent Application No. 10-2023-0171630, filed on Nov. 30, 2023, which is hereby incorporated by reference as if fully set forth herein.

### BACKGROUND

### Technical Field

The present disclosure relates to a light emitting display device, and more particularly, to a light emitting display device that can improve luminance uniformity of a display area.

### Discussion of the Related Art

Display devices that display various information on a screen are a key technology of the information and communication era, and various display devices with excellent performance, such as thinness, lightness, and low power consumption, are continuously being developed. Thereamong, a light emitting display device includes a light emitting element spontaneously capable of emitting light and thus does not require a separate light source used in a non-light emitting element, thus realizing reduced weight and thickness.

The light emitting element includes an intermediate layer between a first electrode and a second electrode, and emits light when an electric field is applied between the first and second electrodes. A light emitting display device may be provided with the second electrode throughout the display area. In this case, the light emitting display device may have a problem in which a luminance difference occurs between respective regions due to the difference in distance from the power source to which the common voltage is applied.

### SUMMARY

Accordingly, embodiments of the present disclosure are directed to a light emitting display device that substantially obviates one or more problems due to the limitations and disadvantages of the related art.

An aspect of the present disclosure is to provide a light emitting display device that includes an auxiliary electrode in a display area and is provided with a connection electrode that electrically connects a second electrode to the auxiliary electrode to uniformly transmit current throughout the display area and, thereby, to uniformize the luminance within the display area.

Another aspect of the present disclosure is to provide a light emitting display device that is provided with a barrier on the auxiliary electrode to separate a material for the intermediate layer and is provided with a connection electrode between the separated intermediate layer and an intermediate dummy pattern through a pattern-defining layer, thereby reducing the contact resistance between the auxiliary electrode and the second electrode, and supplying uniform current throughout the display area.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

The light emitting display device may include an auxiliary electrode in the display area, may include a barrier on the auxiliary electrode to separate the material for the intermediate layer, and may include a connection electrode electrically connects the second electrode to the auxiliary electrode through a pattern-defining layer between the separated intermediate layer and the intermediate dummy pattern. Thus, light emitting display device may supply uniform current to the entire display area and uniformizing the luminance within the display area.

To achieve these and other aspects of the inventive concepts, as embodied and broadly described herein, a light emitting display device, including a plurality of sub-pixels that each have a light emitting area, comprises a substrate; a first electrode at each light emitting area on the substrate; an intermediate layer and a second electrode on the first electrode; an auxiliary electrode at a non-light emitting area and spaced apart from the first electrode on the substrate; a bank exposing the light emitting area and the auxiliary electrode; a first partition on the auxiliary electrode and configured to expose a portion of the auxiliary electrode; a first pattern-defining layer on the first partition; and a connection electrode on the auxiliary electrode and electrically connected to the second electrode.

In another aspect, a light emitting display device, including a plurality of sub-pixels that each have a light emitting area, comprises a substrate; a first electrode at each light emitting area on the substrate; an auxiliary electrode at a non-light emitting area and spaced apart from the first electrode on the substrate; a bank exposing the light emitting area and the auxiliary electrode; a first partition spaced from the bank and on the auxiliary electrode; a second electrode on the first electrode and the bank; a second electrode dummy pattern in a same layer as the second electrode and on the first partition; a pattern-defining layer on the bank and on the first partition to be in a same layer as the second electrode and the second electrode dummy pattern; and a connection electrode contacting each of the second electrode, the second electrode dummy pattern at a portion exposed from the pattern-defining layer, and the auxiliary electrode.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure. In the drawings:

FIG. 1 is a schematic plan view illustrating a light emitting display device of the present disclosure;

FIG. 2 is an enlarged plan view illustrating a portion illustrating a display area of FIG. 1;

FIGS. 3A and 3B are enlarged views illustrating A in FIG. 2 according to a first embodiment;

FIG. 4 is a cross-sectional view taken along line I-I′ of FIG. 3A;

FIGS. 5A and 5B are enlarged views illustrating A in FIG. 2 according to a second embodiment;

FIG. 6 is a cross-sectional view taken along line II-II′ of FIG. 5A;

FIGS. 7A and 7B are enlarged views illustrating A in FIG. 2 according to a third embodiment;

FIG. 8 is a cross-sectional view taken along line III-III′ of FIG. 7A;

FIGS. 9A and 9B are enlarged views illustrating A in FIG. 2 according to a fourth embodiment;

FIG. 10 is a cross-sectional view taken along line IV-IV′ of FIG. 9A;

FIGS. 11 to 13 are plan views illustrating various types of barriers;

FIGS. 14A to 14E are cross-sectional views illustrating a process according to the second embodiment; and

FIGS. 15A to 15D are cross-sectional views illustrating a process according to the fourth embodiment.

### DETAILED DESCRIPTION

The advantages and features of the present disclosure and methods of accomplishing the same will be clearly understood from the following example embodiments with reference to the attached drawings. However, the present disclosure is not limited to the embodiments, and may be embodied in different forms. The embodiments are suggested only to offer a thorough and complete understanding of the disclosed context and to sufficiently inform those skilled in the art of the technical concept of the present disclosure and embodiments of the present disclosure are only defined by the scope of the claims.

The shape, size, ratio, angle, number, and the like shown in the drawings to illustrate various embodiments of the present disclosure are merely provided for illustration, and the disclosure is not limited to the content shown in the drawings. Wherever possible, the same reference numbers will be used throughout the drawings to refer to the same or like parts. In the following description, detailed descriptions of technologies or configurations related to the present disclosure may be omitted so as to avoid unnecessarily obscuring the subject matter of the present disclosure.

When terms such as “including,” “having,” and “comprising” are used throughout the disclosure, an additional component may be present, unless “only” is used. A component described in a singular form encompasses a plurality thereof unless particularly stated otherwise.

The components included in the embodiments of the present disclosure should be interpreted to include an error range, even if there is no additional particular description thereof.

In describing the variety of embodiments of the present disclosure, when terms describing positional relationships such as “on,” “above,” “under,” and “next to” are used, at least one intervening element may be present between the two elements, unless “immediately” or “directly” is also used.

In describing the variety of embodiments of the present disclosure, when terms related to temporal relationships, such as “after,” “subsequently,” “next,” and “before,” are used, the non-continuous case may be included, unless “immediately” or “directly” is also used.

In describing the variety of embodiments of the present disclosure, terms such as “first” and “second” may be used to describe a variety of components, but these terms only aim to distinguish the same or similar components from one another. Accordingly, throughout the disclosure, a “first” component may be the same as a “second” component within the technical concept of the present disclosure, unless specifically mentioned otherwise.

The terms “first horizontal axis direction,” “second horizontal axis direction,” and “vertical axis direction” should not be interpreted as only geometric relationships in which the relationship between each other is vertical, and as having a broader range of direction as long as the configuration of the present disclosure can serve functionally.

The term “at least one” should be understood to include all possible combinations of one or more related items. For example, “at least one of the first, second, and third items” means each of the first, second, or third items, as well as any combination of two or more of the first, second, and third items.

Features of various embodiments of the present disclosure may be partially or completely coupled to or combined with each other, and may be variously inter-operated with each other and driven technically. The embodiments of the present disclosure may be carried out independently from each other, or may be carried out together in an interrelated manner.

In adding reference numerals to components in each drawing, identical components may have the same reference numerals as much as possible even if they are shown in different drawings. In addition, the scale of the components shown in the attached drawings has a different scale from the actual scale for convenience of explanation and is thus not limited to the scale shown in the drawings.

Hereinafter, examples of a light emitting display device according to the present disclosure will be described in detail with reference to the drawings.

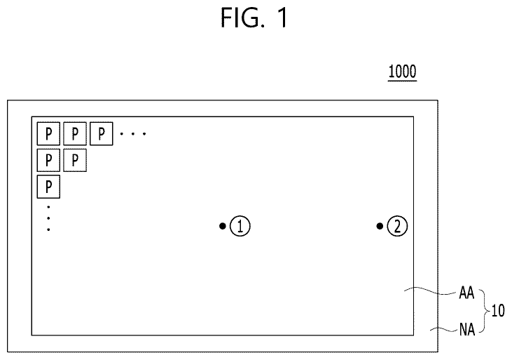

FIG. 1 is a schematic plan view illustrating a light emitting display device of the present disclosure.

With reference to FIG. 1, the light emitting display device 1000 of the present disclosure may include a substrate 10 including a display area AA and a non-display area NA, and a plurality of pixels P provided in the display area AA.

The substrate 10 may be divided into the display area AA where a screen is present and the non-display area NA where the screen is not present. Such a substrate 10 may be formed of glass or a flexible plastic substrate. For example, when the substrate 10 is a plastic substrate, it may include polyimide or polyamide.

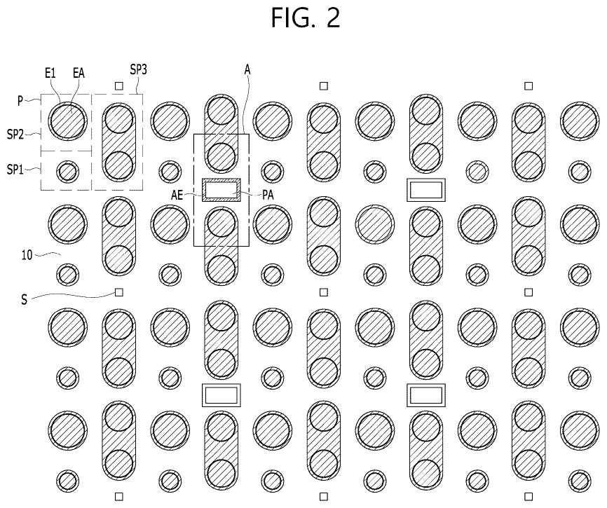

The display area AA may include a plurality of pixels P. A power supply voltage line may be formed in the non-display area NA. A second electrode facing the first electrode may be formed over the entire surface of the display area AA and the non-display area NA. The second electrode is electrically connected to the power supply voltage line of the non-display area NA and can supply a common voltage from the power supply voltage line to the entire display area AA. In this case, due to the resistance of the second electrode, the first region 1, which is relatively far from the non-display area NA, may receive less common voltage than the second region 2 close thereto. However, the light emitting display device 1000 of the present disclosure can prevent a voltage drop of the second electrode through the auxiliary electrode (AE in FIG. 2) electrically connected to the power supply voltage line provided in the display area AA.

FIG. 2 is an enlarged plan view illustrating a portion of the display area AA of FIG. 1.

With reference to FIG. 2, the light emitting display device 1000 of the present disclosure includes a plurality of pixels P including a first sub-pixel SP1, a second sub-pixel SP2, and a third sub-pixel SP3, each having a light emitting area EA, wherein an auxiliary electrode AE and an auxiliary line PA overlapping the auxiliary electrode AE are provided in the non-light emitting area NEA, and a spacer S is provided in the non-light emitting area NEA. Each of the plurality of sub-pixels P may include a plurality of sub-pixels SP1, SP2, and SP3. Each of the sub-pixels SP1, SP2, and SP3 may include a light emitting area EA. The plurality of sub-pixels SP1, SP2, and SP3 may each include a light emitting area EA that emits different colors. For example, the first sub-pixel SP1 may be a sub-pixel having a light emitting area EA that emits red light, the second sub-pixel SP2 may be a sub-pixel having a light emitting area EA that emits green light, and the third sub-pixel SP3 may be a sub-pixel having a light emitting area EA that emits blue light.

The first to third sub-pixels SP1, SP2, and SP3 may have different areas. The area of each of the first to third sub-pixels SP1, SP2, and SP3 may be determined in consideration of the lifespan and luminous efficacy of the light emitting device of the corresponding color. A sub-pixel that emits short-wavelength light may have a larger area than other sub-pixels, and a sub-pixel that emits long-wavelength light may have a smaller area than other sub-pixels. As a result, the light emitting display device of the present disclosure has different area ratios of sub-pixels that emit light of different colors, thereby uniformizing the lifespan and luminous efficacy of each light emitting element. For example, when the third sub-pixel SP3 has a short-wavelength light emitting area EA that emits blue light, it has a larger area than the first and second sub-pixels SP1 and SP2 having light emitting areas EA that emits red and green light, respectively. In this case, the third sub-pixel SP3 may have two light emitting areas EA, but the present disclosure is not limited thereto and the third sub-pixel SP3 may include sub-pixels with various structures.

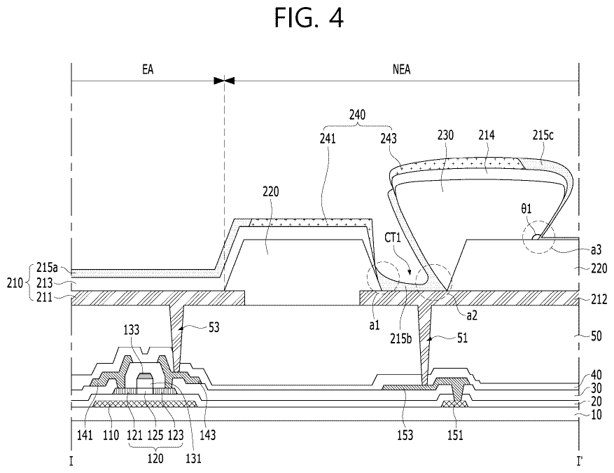

The light emitting area EA may have a size corresponding to the area of each sub-pixel SP1, SP2, and SP3. The light emitting area EA may be defined as a region exposed by the bank (220 in FIG. 4). Meanwhile, the bank 220 may expose the auxiliary electrode AE and may be provided in the entire area excluding the light emitting area EA and a portion of the auxiliary electrode AE.

The non-light emitting area NEA may include an auxiliary electrode AE spaced apart from the first electrode E1. The auxiliary electrode AE may be formed as a same layer as the first electrode E1. The auxiliary electrode AE may be provided between the first electrodes E1 and may be provided in a partial area between the first electrodes E1, as shown in FIG. 2. In addition, the auxiliary electrode AE may be provided between the third sub-pixels SP3 where the light emitting area EA is relatively large, but the present disclosure is not limited thereto and the auxiliary electrode AE may have various arrangement structures.

An auxiliary line PA overlapping the auxiliary electrode AE may be provided. The auxiliary line PA may be electrically connected to the auxiliary electrode AE. In addition, the auxiliary line PA may extend to the power supply voltage line of the non-display area NA and may be electrically connected to the power supply voltage line. Accordingly, the auxiliary line PA may supply the voltage of the power voltage line to the auxiliary electrode AE. This auxiliary line PA may have an area corresponding to the auxiliary electrode AE.

The spacer S may be further provided in the non-light emitting area NEA. The spacer S may be provided as the same layer in the same process as the first partition 230 described below. The spacer S may have a predetermined height from the top of the bank 220 and the height thereof may be larger than the height of the bank 220. The spacer S may function to support a fine metal mask (FMM) during the process. As a result, the spacer S can prevent sagging of the fine metal mask.

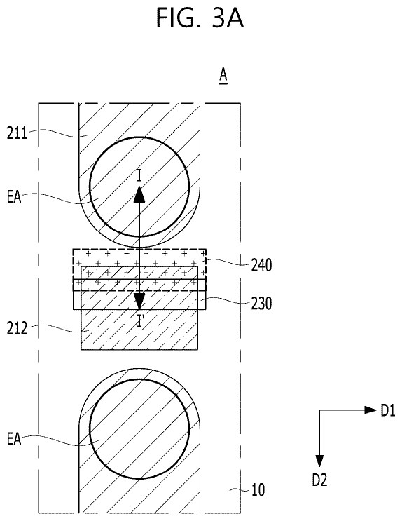

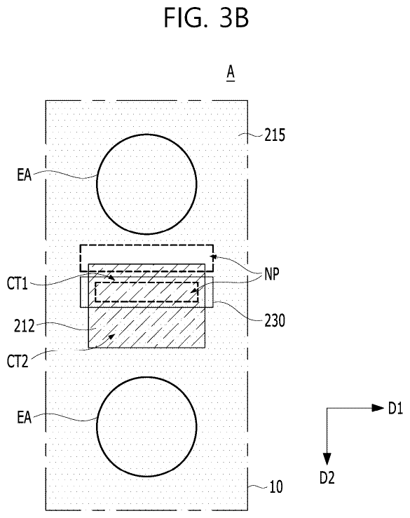

FIGS. 3A and 3B are enlarged views illustrating A in FIG. 2 according to a first embodiment. FIG. 3A schematically illustrates the area of the pattern-defining layer 240. FIG. 3B schematically illustrates the areas of the second electrode patterns 215 (215a, 215b, 215c). FIG. 4 is a cross-sectional view taken along line I-I′ of FIG. 3A.

The light emitting display device according to an embodiment of the present disclosure includes a substrate including a plurality of sub-pixels each having a light emitting area, a first electrode provided in each light emitting area on the substrate, an intermediate layer and a second electrode sequentially provided on the first electrode, an auxiliary electrode provided in the non-light emitting area on the substrate and spaced apart from the first electrode, a bank exposing the light emitting area and the auxiliary electrode, a first partition provided on the auxiliary electrode and exposing a part of the auxiliary electrode, a first pattern-defining layer provided on the first partition, and a connection electrode provided on the auxiliary electrode and electrically connected to the second electrode.

With reference to FIGS. 3A and 3B, according to the first embodiment of the present disclosure, an auxiliary electrode 212 is provided in the non-light emitting area NEA, a first partition 230 overlapping the auxiliary electrode 212 is provided, a pattern-defining layer 240 overlapping the first partition 230 is provided, and second electrode patterns 215 (215a, 215b, 215c) are provided around the pattern-defining layer 240.

Accordingly, the first partition 230 may overlap the auxiliary electrode 212 in a first direction D1. The length of the first partition 230 in the first direction D1 may be greater than its length in the second direction D2 perpendicular to the first direction D1. In addition, the length of the first partition 230 in the first direction D1 may be longer than the length of the auxiliary electrode 212 in the first direction D1. The length of the first partition 230 in the first direction D1 may be greater than the length of the light emitting area EA in the first direction D1. Accordingly, when the second electrode pattern 215 and the auxiliary electrode 212 come into contact with the edge of the first partition 230, the contact area between the second electrode pattern 215 and the auxiliary electrode 212 corresponding to the length in the first direction D1 of the first partition 230 can be secured.

As shown in FIG. 3B, in the area where the second electrode pattern 215 overlaps the first partition 230, the second electrode pattern 215 has a first contact portion CT1 electrically connected to the auxiliary electrode 212. In addition, the second electrode pattern 215 may have a second contact portion CT2 that does not overlap the first partition 230 and is electrically connected to the auxiliary electrode 212 exposed from the bank (220 in FIG. 4).

The pattern-defining layer 240 according to the first embodiment may be provided from the first partition 230 to the area between the first electrode 211 and the auxiliary electrode 212. Moreover, the pattern-defining layer 240 according to the first embodiment may be provided on a part of the first partition 230. The pattern-defining layer 240 is spaced apart from one side surface of the first partition 230 so that formation of second electrode patterns 215 with different thicknesses may be possible on the side surface of the first partition 230, as shown in portions a1, a2, and a3 of FIG. 4.

The second electrode pattern 215 may be formed over the entire surface of the substrate 10 excluding the pattern-defining layer 240. The pattern defining layer 240 comprises a material having a low affinity for a conductive material, such as the second electrode pattern 215. Depending on the shape of the first partition 230, the second electrode pattern 215 may overlap the pattern-defining layer 240, when viewed in the plane. In the light emitting display device of the present disclosure, the first partition 230 has a reverse taper shape so that the second electrode pattern 215 formed of a metal with excellent step coverage can also be formed on the side surface of the first partition 230. In this case, the second electrode pattern 215 may overlap the edge of the first partition 230, as shown in FIG. 3B. However, the second electrode pattern 215 may have a non-pattern area (NP) in which no material is deposited by the pattern-defining layer 240. For example, the non-pattern area NP of the second electrode pattern 215 may be provided in the area between the first partition 230 and the light emitting area EA and within the first partition 230. With reference to FIG. 4 together, the non-pattern area NP provided in the first partition 230 may correspond to a surface of the first partition 230 overlapping the pattern-defining layer 240 while contacting the bank 220.

The second electrode pattern 215 may be formed in a region excluding the non-pattern area NP while overlapping the first partition 230 and may have a first contact portion CT1 with the auxiliary electrode 212. In addition, the second electrode pattern 215 is an area that does not overlap the first partition 230 while overlapping the auxiliary electrode 212 exposed from the bank 220, and may be in contact with the auxiliary electrode 212. Accordingly, the second electrode pattern 215 is connected to the auxiliary electrode 212 to enable the power voltage to be supplied between the light emitting areas EA.

With reference to FIG. 4, the light emitting display device of the present disclosure includes a transistor (TFT), a first electrode 211 connected to the transistor TFT, and a light emitting element 210 including the first electrode 211, an intermediate layer 213, and second electrode patterns (215; 215a, 215b, 215c) in a light emitting area EA on the substrate 10, and further includes a first auxiliary line 151, a second auxiliary line 153, and an auxiliary electrode 212 connected to the second auxiliary line 153 in a non-light emitting area NEA on the substrate. In addition, the light emitting display device of the present disclosure includes a bank 220 and a first partition 230 provided on the first electrode 211 and the auxiliary electrode 212, and a pattern-defining layer 240 for patterning the second electrode pattern 215.

Various signal wires, such as data signals and gate signals, transistors, such as switching thin film transistors and driving thin film transistors, and circuit elements including capacitors may be formed in each sub-pixel SP on the substrate 10. For convenience of explanation, a single transistor TFT driving one light emitting element 210 is illustrated.

The transistor TFT includes an active layer 120, a gate electrode 133 overlapping a channel region 125 of the active layer 120 with a gate insulating film 131 therebetween, and a source electrode 141 and a drain electrode 143 connected to both sides of the active layer 120. The active layer 120 of the transistor TFT includes a source region 121 and a drain region 123 on both sides thereof with a channel region 125 therebetween. Each of the source region 121 and the drain region 123 is formed of a semiconductor material doped with n-type or p-type impurities. The channel region 125 overlapping the gate electrode 133 may be formed of a semiconductor material not doped with n-type or p-type impurities.

The gate electrode 133 of the transistor TFT is provided to overlap the channel region 125 of the active layer 120, while having the same width as the channel region 125, with the gate insulating film 131 interposed therebetween. The gate insulating film 131 overlaps the channel region 125 of the active layer 127 in the same pattern as the gate electrode 133. For example, the gate electrode 133 may be a single layer or multiple layers containing one of molybdenum (Mo), aluminum (Al), chromium (Cr), gold (Au), titanium (Ti), nickel (Ni), neodymium (Nd), and copper (Cu), or an alloy thereof. Meanwhile, the gate insulating film 131 may contain an inorganic insulating material, and may include, for example, a silicon oxide (SiOx) film, a silicon nitride (SiNx) film, a silicon oxynitride (SiOxNy) film, or multiple films thereof.

Meanwhile, the light-blocking layer 110 on the substrate 10 overlaps at least the channel region 125 of the active layer 120 of the transistor TFT and is disposed below the active layer 120. The light-blocking layer 110 prevents external light from penetrating the substrate 10 and being transmitted to the transistor TFT. For example, the light-blocking layer 110 may be a single layer containing a metal material, such as molybdenum (Mo), titanium (Ti), aluminum-neodymium (AlNd), aluminum (Al), chromium (Cr), or an alloy thereof, or a multilayer structure using the same.

The buffer film 20 on the light-blocking layer 110 is provided to cover the light-blocking layer 110. For example, the buffer film 20 may have a single-layer or multilayer structure containing silicon oxide (SiOx) or silicon nitride (SiNx).

The interlayer insulating film 30 on the buffer film 20 includes a source contact hole and a drain contact hole exposing each of the source region 121 and the drain region 123 of the active layer 120, and covers the gate insulating film 131 and the gate electrode 133. In this case, the interlayer insulating film 30 may contain an inorganic insulating material. For example, the interlayer insulating film 30 may be a single layer or multiple layers containing a silicon oxide (SiOx) film, a silicon nitride (SiNx) film, or a silicon oxynitride (SiOxNy) film.

The source electrode 141 and the drain electrode 143 may be provided in the same layer on the interlayer insulating film 30. Each of the source electrode 141 and the drain electrode 143 is connected to the source region 121 and drain region 123 of the active layer 120 through a source contact hole and a drain contact hole. For example, the source electrode 141 and the drain electrode 143 may be a single layer containing a metal material, such as molybdenum (Mo), aluminum (Al), chromium (Cr), gold (Au), titanium (Ti), nickel (Ni), neodymium (Nd), copper (Cu), or an alloy thereof, or a multilayer structure using the same.

The passivation layer 40 on the interlayer insulating film 30 may be provided to cover the transistor TFT region. As a result, the transistor TFT can be protected by the passivation layer 40. For example, the passivation layer 40 is a type of inorganic insulating film and may be provided as a single layer or multiple layers of a silicon oxide (SiOx) film, a silicon nitride (SiNx) film, or a silicon oxynitride (SiOxNx) film.

A planarization layer 50 may be provided on the passivation layer 40. The planarization layer 50 is formed to a thickness sufficient to planarize the surface step at the top of the transistor TFT region and may be formed of an organic insulating film. In some cases, when the planarization layer 50 also functions to protect the transistor TFT, the passivation layer 40 may be omitted. For example, the planarization layer 50 is a type of organic insulating film and may be any one of photoacryl, polyimide, benzocyclobutene resin, and acrylate. In some cases, the planarization layer 50 may be formed in multiple layers.

Meanwhile, a first auxiliary line 151 and a second auxiliary line 153 may be provided on the substrate 10. A plurality of first and second auxiliary lines 151 and 153 are provided in the display area AA and may be electrically connected to the auxiliary electrode 212. In addition, the first and second auxiliary lines 151 and 153 may transmit the common voltage from the power voltage line provided in the non-display area NA outside the display area AA to the auxiliary electrode 212. The first auxiliary line 151 and the second auxiliary line 153 may be provided as a single layer, and the first auxiliary line 151 and the second auxiliary line 153 may intersect each other. In addition, the second auxiliary line 153 may be formed in a size corresponding to the auxiliary electrode 212, and the first and second auxiliary lines 151 and 153 of the present disclosure are not limited thereto. For example, the first and second auxiliary lines 151 and 153 are each formed of any one(s) selected from the group consisting of molybdenum (Mo), aluminum (Al), chromium (Cr), gold (Au), titanium (Ti), nickel (Ni), neodymium (Nd), or copper (Cu), or an alloy containing at least one thereof.

The auxiliary electrode 212 may be connected to the second auxiliary line 153 through a first contact hole 51 in the planarization layer 50 and the passivation layer 40. The first electrode 211 may be connected to the drain electrode 143 of a transistor through a second contact hole 53 in the planarization layer 50 and the passivation layer 40.

A light emitting element 210 including a stack structure of a first electrode 211, an intermediate layer 213, and a second electrode 215a may be provided on the planarization layer 50. In addition, the light emitting element 210 may be operated based on the mechanism in which, when current is supplied from the power voltage line to the second electrode 215a and a high-voltage current is supplied from the transistor TFT to the first electrode 211, an electric field is formed between the first electrode 211 and the second electrodes 215a, and the intermediate layer 213 emits light. At this time, the light emitting area EA, which is a region where light is emitted from the light emitting element 210, may be exposed from the bank 220.

The first electrode 211 may be provided in each of the plurality of sub-pixels SP1, SP2 and SP3 and may be electrically connected to the transistor TFT. The first electrode 211 may be formed in a multilayer structure including a transparent conductive film and an opaque conductive film with high reflection efficiency. The transparent conductive film of the first electrode 211 may include a material with a relatively high work function value, such as indium tin oxide (ITO) or indium zinc oxide (IZO), and the opaque conductive film may be a single layer or multiple layers containing any one or an alloy thereof selected from the group consisting of silver (Ag), aluminum (Al), copper (Cu), molybdenum (Mo), titanium (Ti), nickel (Ni), chromium (Cr), and tungsten (W). For example, the first electrode 211 may have a structure in which a transparent conductive film, an opaque conductive film, and a transparent conductive film are sequentially stacked, or a structure in which a transparent conductive film and an opaque conductive film are sequentially stacked.

An auxiliary electrode 212 may be provided on the planarization layer 50 such that it is spaced apart from the first electrode 211. The auxiliary electrode 212 may receive voltage from a power voltage line provided in the non-display area through the first auxiliary line 151 and the second auxiliary line 153. The auxiliary electrode 212 is provided in any region of the non-light emitting area NEA and contacts the connection electrode 215b, thereby supplying the voltage from the first and second auxiliary lines 151 and 153 to the second electrode 215a. The auxiliary electrode 212 contacts the connection electrode 215b, thereby uniformly supplying the voltage of the power supply voltage line to the entire region of the display area AA.

The bank 220 may be provided to cover the edge of the first electrode 211. In addition, the bank 220 may also cover the edge of the auxiliary electrode 212. The bank 220 according to the first embodiment may be provided not only at the edge of the auxiliary electrode 212 but also on a part of the auxiliary electrode 212. However, the bank 220 may expose a part of the light emitting area EA and the auxiliary electrode 212. As a result, components formed next to the bank 220 may be deposited on the auxiliary electrode 212 exposed by the bank 220 and come into contact with the auxiliary electrode 212. For example, the bank 220 is formed of an organic material, such as a polyimide, acrylate, or benzocyclobutene resin.

The present disclosure according to the first embodiment may include a first partition 230 on the bank 220 provided on the auxiliary electrode 212. The first partition 230 provided on the bank 220 may form a larger step from the auxiliary electrode 212 than when provided directly on the auxiliary electrode 212. Accordingly, the first partition 230 provided on the bank 220 may be used as a common mask to more easily separate the material for the intermediate layer 213 deposited on the top and the second electrode pattern 215.

The first partition 230 may have a width which decreases from the top surface to the bottom surface. For example, the first partition 230 may be formed in a reverse taper shape. The first partition 230 having a reverse taper shape may disconnect the material for the second electrode pattern 215 and the material for the intermediate layer 213 formed at the top. At this time, the side surface of the first partition 230 may have an internal angle with respect to the substrate 10 of a first angle θ1. The first angle θ1 of the side surface of the first partition 230 may be not less than 90° and less than 180°. In order for a metal having excellent step coverage to be deposited on the side of the first partition 230, the first angle θ1 may be 120° or more and 135° or less. Accordingly, as shown in FIG. 4, the second electrode 215c may be formed on the side surface of the first partition 230 on the auxiliary electrode 212 and the top surface of the bank 220 in contact with the first partition 230.

An intermediate layer 213 and an intermediate dummy pattern 214 may be provided on the bank 220 and the first partition 230, respectively. The intermediate layer 213 and the intermediate dummy pattern 214 may be formed in the same process and may contain the same material. The materials constituting the intermediate layer 213 and the intermediate dummy pattern 214 may be deposited over the entire surface of the substrate 10 as a common mask and may be separated from each other around the first partition 230 by the first partition 230 having a reverse taper shape. Accordingly, the intermediate layer 213 on the light emitting area EA may be separated into the intermediate dummy pattern 214 through the first partition 230 in the non-light emitting area NEA.

The intermediate layer 213 may refer to a single stack organic layer including multiple layers including a hole injection layer (HIL), a hole transport layer (HTL), a light emitting layer (EML1 or EML2), an electron transport layer (ETL), and an electron injection layer (EIL). However, the intermediate layer 213 has a light emitting unit with a tandem structure including a plurality of stacks (first stack and second stack), each having first and second light emitting layers (EML1 and EML2), and a charge generation layer (CGL) between the stacks. The tandem structure is not limited to the two-stack structure shown and may include multiple stacks of three or more stacks. Here, the first and second light emitting layers (EML1, EML2) in the plurality of stacks may be light emitting layers of the same color that emit one of red, green, and blue light, and are partially provided in each of the sub-pixels SP. A plurality of layers of the intermediate layer 213 excluding the first and second light emitting layers (EML1 and EML2) may be provided as a common mask over the entire surface of the substrate 10. Alternatively, when white light is emitted by the first and second light emitting layers (EML1 and EML2) in a two-stack structure or through the light emitting layers in a multiple stack structure of three or more stacks, each of the light emitting layers may be provided over the entire surface of the substrate 10, like the other intermediate layers 213. Meanwhile, the charge generation layer (CGL) may be formed of a double-layer structure including n-type and p-type layers.

The second electrode patterns 215 (215a, 215b, 215c) may be formed over the entire surface of the substrate 10 through a common mask. For example, the second electrode pattern 215 has a configuration in which a second electrode 215a on the light emitting area EA, a second electrode 215c on the bank 220 in contact with the first partition 230, and a connection electrode 215b interposed between the two components are integrally connected with each other (e.g., in a plan view of the device). However, the second electrode pattern 215 according to the first embodiment may be provided in an area excluding a pattern-defining portion 240. In other words, the second electrode pattern 215 is divided into a second electrode 215a provided in the light emitting area EA and a second electrode 215c provided in the non-light emitting area NEA based on the pattern-defining layer 240, and may include a connection electrode 215b in contact with the auxiliary electrode 212 between the two components. The second electrode pattern 215 formed of a metal has excellent step coverage characteristics compared to the intermediate layer 213 formed of an organic material or a combination of organic and inorganic materials, and thus may be formed to cover the side surface of the first partition 230, like the second electrode 215c and the connection electrode 215b provided in the non-light emitting area NEA of FIG. 4. In addition, with reference to FIG. 3B, the second electrode pattern 215 has some discontinuous sections within the pattern-defining layer 240, but the second electrode 215a provided in the light emitting area EA and the second electrode 215c provided in the non-light emitting area NEA may be integrated through the connection electrode 215b. For example, the second electrode pattern 215 may be formed of a transparent conductive material, such as indium tin oxide (ITO) or indium zinc oxide (IZO), and may be formed of silver (Ag), aluminum (Al), magnesium (Mg) or calcium (Ca) having a thickness small enough to transmit light, or an alloy thereof.

The connection electrode 215b provided between the first pattern-defining layer 241 and the second pattern-defining layer 243 may be thicker at edge regions a1 and a2 than an inner space between the edge regions a1 and a2, as shown in FIG. 4. For example, the thickness of the connection electrode 215b provided near the edge between the auxiliary electrode 212 and the first partition 230 is greater than the thickness of the second electrode 215c provided on the first partition 230 adjacent to the second pattern-defining layer 243.

The connection electrode 215b according to the first embodiment is formed due to low affinity for the pattern-defining layer 240 when the material of the second electrode is deposited over the entire surface of the substrate 10 after the pattern-defining layer 240 is formed. The pattern defining layer 240 may comprise a material having a low affinity for a conductive material as compared to the material of the intermediate layer 213 or the intermediate dummy pattern 214. For example, the material for the second electrode deposited on top of the pattern-defining layer 240 may not adhere to (or be repelled by) the surface of the pattern-defining layer 240 and may be detached therefrom due to low affinity for the pattern-defining layer 240. The material for the second electrode detached from the surface of the pattern-defining layer 240 may evaporate or flow into a lower location along the surface of the pattern-defining layer 240. Here, the lower location may include a valley shape defined between the bank 220 and the first partition 230. Accordingly, the material for the second electrode deposited on the pattern-defining layer 240 flows between the first and second pattern-defining layers 241 and 243, which are separated from each other, may be especially formed to a great thickness near the edges, as shown in a1 and a2 of FIG. 4. For this reason, the light emitting display device of the present disclosure has a pattern-defining layer 240 on the first partition 230 having a reverse taper shape, thereby reducing contact resistance at a first contact portion CT1 between the connection electrode 215b and the auxiliary electrode 212.

Meanwhile, the second electrode 215c formed on the side surface of the first partition 230 without being affected by the pattern-defining layer 240 may be very thin, as shown in a3 of FIG. 4. The second electrode 215c in a3 of FIG. 4 may be much thinner than the second electrode 215a on the light emitting area EA. For example, the second electrode 215c formed on the side surface of the first partition 230 at a predetermined distance from the pattern-defining layer 240 is hardly affected by the pattern-defining layer 240, thus increasing resistance in the thin area, as shown in a3 of FIG. 4.

The pattern-defining layer 240 may include a first pattern-defining layer 241 and a second pattern-defining layer 243 on the bank 220 and the first partition 230, respectively. The first and second pattern-defining layers 241 and 243 may be formed in the same process, and may be separated from each other by the first partition 230 having a reverse taper shape, as described above.

The pattern-defining layer 240 may have a low affinity for a conductive material and may have a surface where deposition of the second electrode pattern 215 formed of a conductive material is suppressed. The conductive material may not be adhered to the surface of the pattern-defining layer 240 due to low affinity for the material for forming the pattern-defining layer 240. In other words, the conductive material constituting the second electrode pattern 215 may have a very low surface adhesion probability to the pattern-defining layer 240. Here, the surface adhesion probability is measured by depositing the amount of conductive material required to form a closed-pack layer with an average thickness of 1 nm on the surface of the pattern-defining layer 240 when the conductive material is deposited. For example, the conductive material is simultaneously deposited on the surface of the pattern-defining layer 240 and the substrate, and the probability of surface adhesion of the conductive material to the pattern-defining layer 240 may be obtained by comparing the average thickness of the conductive material deposited on the substrate when the average thickness of the dense layer on the surface of the pattern-defining layer 240 reaches 1 nm. The probability of surface adhesion of the conductive material to the pattern-defining layer 240 may be 0.0008 (or 0.08%) to 0.3 (or 30%). Accordingly, during the nucleation and growth process, conductive materials may be desorbed and evaporated due to low affinity for the pattern-defining layer 240, or may flow and be fixed to another surface.

For example, the pattern-defining layer 240 is an organic material including an organic polymer, and may contain a polycyclic aromatic compound containing at least one heteroatom, such as N (nitrogen), S (sulfur), O (oxygen), phosphorus (P), or aluminum (Al). The polycyclic aromatic compound may include an organic molecule including a core moiety and at least one terminal moiety bonded to the core moiety. For example, the material for the pattern-defining layer 240 is 3-(4-biphenyl)-4-phenyl-5-tert-butylphenyl-1,2,4-triazole (TAZ), aluminum (III) bis(2-methyl-8-quinolinato)-4-phenylphenolate (BA1q), 2-(4-(9,10-di(naphthalen-2-yl) anthracen-2-yl)phenyl)-1-phenyl-1H-benzo-[D]imidazole, 8-hydroxyquinoline lithium (Liq), N (diphenyl-4-yl) 9,9-dimethyl-N-(4 (9-phenyl-9H-carbasol-3-yl)phenyl)-9H-fluoren-2-amine, or the like.

Meanwhile, an encapsulation film may be provided on the second electrode pattern 215. The encapsulation film completely covers the display area and the non-display area. The encapsulation film prevents oxygen and moisture from penetrating into the light emitting element 210, thereby increasing the lifespan of the light emitting display device. For example, the encapsulation film may be formed by stacking one or more pairs of an inorganic encapsulation film and an organic encapsulation film, or may be formed by stacking a filler material and a counter substrate.

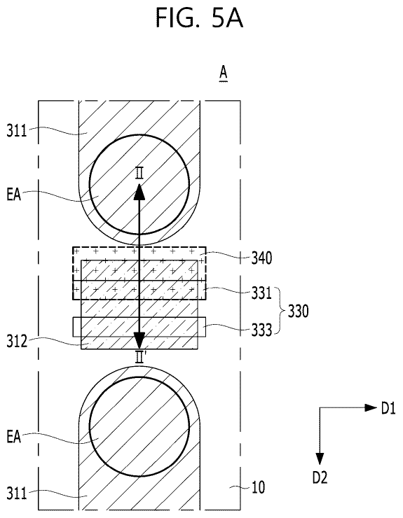

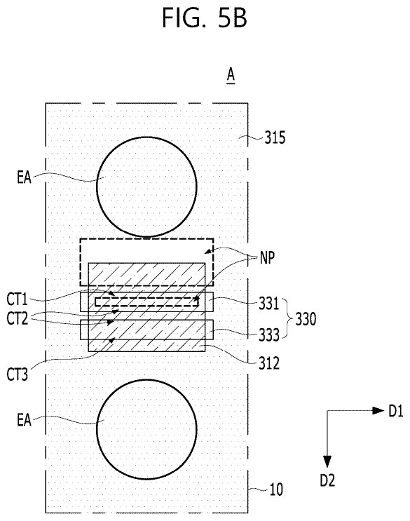

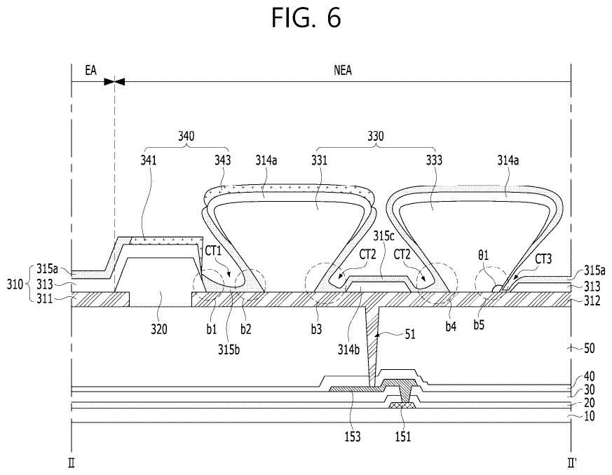

FIGS. 5A and 5B are enlarged views illustrating A in FIG. 2 according to a second embodiment. FIG. 5A schematically illustrates the area of the pattern-defining layer 340, and FIG. 5B schematically illustrates the area of the second electrode pattern 315 (315a, 315b, 315c). FIG. 6 is a cross-sectional view taken along line II-II′ of FIG. 5A. Hereinafter, description of the same configuration as in the previous embodiment will be omitted.

With reference to FIGS. 5A and 5B, according to the second embodiment of the present disclosure, an auxiliary electrode 312 is provided in the non-light emitting area NEA, a first partition 331 and a second partition 333 overlapping the auxiliary electrode 312 are provided, a pattern-defining layer 340 overlapping the first partition 331 is provided, and second electrode patterns 315 (315a, 315b, 315c) are provided around the pattern-defining layer 340. Accordingly, the partition 330 according to the second embodiment may include a first partition 331 and a second partition 333. The first partition 331 and the second partition 333 according to the second embodiment may be spaced apart from each other and parallel to each other when viewed in the plane. For example, the first partition 331 and the second partition 333 may be provided in the first direction D1 and spaced apart from each other in the second direction D2. Like the first partition 230 according to the first embodiment, each of the first and second partitions 331 and 333 according to the second embodiment has a length in the first direction D1 that is greater than a length in the first direction D1 of the light emitting area EA, thereby securing the contact area between the second electrode pattern 315 and the auxiliary electrode 312 corresponding to the length of the partition 330 in the first direction D1.

The pattern-defining layer 340 according to the second embodiment may be provided from the first partition 331 to the area between the first electrode 311 and the auxiliary electrode 312. The pattern-defining layer 340 according to the second embodiment may not be provided on the second partition 333.

The second electrode pattern 315 may be formed over the entire surface of the substrate 10 excluding an area partially overlapping the pattern-defining layer 340. In other words, the second electrode pattern 315 may be formed over the entire surface of the substrate 10 excluding the non-pattern area NP. For example, the non-pattern area NP may be provided in an area between the first partition 331 and the light emitting area EA and in an area where the first partition 331 is provided. In addition, by appropriately adjusting the first angle θ1 on the side surface of the partition 330, the second electrode pattern 315 with excellent step coverage characteristics may be formed on the side surface of the partition 330. Accordingly, the light emitting display device of the present disclosure according to the second embodiment does not have the pattern-defining layer 340 on the second partition 333, but the second electrode pattern 315 below the side surface of the second partition 333 may be in contact with the auxiliary electrode 312.

As shown in FIG. 5B, the second electrode pattern 315 may have first and second contact portions CT1 and CT2 electrically connected to the auxiliary electrode 312 in the area overlapping the first partition 330. In addition, the second partition 333 may have second and third contact portions CT2 and CT3 at which the second electrode pattern 315 and the auxiliary electrode 312 are electrically connected to each other. Here, the contact resistance of the second electrode pattern 315 may be different from that of the auxiliary electrode 312 in each of the first to third contact portions CT1, CT2, and CT3. In particular, the contact resistance of the third contact portion CT3 with respect to the side surface of the second partition 333 not provided with the pattern-defining layer 340, not adjacent to the first partition 331, may be greater than the contact resistance of the first and second contact portions CT1 and CT2. However, the second partition 333 is not provided with a non-pattern area (NP), thereby providing smooth current movement between the two light emitting areas EA through the second electrode pattern 315.

With reference to FIG. 6, the light emitting display device according to the second embodiment of the present disclosure includes a light emitting element 310 including a first electrode 311, an intermediate layer 313, and a second electrode 315a in a light emitting area EA on a substrate 10, and includes an auxiliary electrode 312, a partition 330, a pattern-defining layer 340, a first connection electrode 315b, and a second connection electrode 315c in a non-light emitting area NEA.

The bank 320 according to the second embodiment may cover the edge of the first electrode 311 and expose the auxiliary electrode 312. In addition, the bank 320 may cover the edge of the auxiliary electrode 312. As the bank 320 exposes the auxiliary electrode 312, the partition 330 may be provided directly on the auxiliary electrode 312.

The partition 330 according to the second embodiment may include a first partition 331 and a second partition 333. The first and second partitions 331 and 333 may have a width which decreases from the top surface to the bottom surface. For example, the first and second partitions 331 and 333 may be formed in a reverse taper shape. The first and second partitions 331 and 333 having a reverse taper shape may separate the material for the second electrode pattern 315 and the material for the intermediate layer 313 formed at the top. At this time, the side surfaces of the first and second partitions 331 and 333 may have an internal angle with respect to the substrate 10 of a first angle θ1. The first angle θ1 of the side surface of the first and second partitions 331 and 333 may be not less than 90° and less than 180°. In order for the second electrode pattern 315 having excellent step coverage to be deposited on the side surface of the first and second partitions 331 and 333, the first angle θ1 may be 120° or more and 135° or less. Accordingly, as shown in b5 of FIG. 6, the second electrode 315a and the second connection electrode 315c contacting the auxiliary electrode 312 may be formed on the side surface of the second partition 333 not provided with the pattern-defining layer 340.

An intermediate layer 313 may be provided on the first electrode 311 and the bank 320, and an intermediate dummy pattern 314a may be provided on each of the first and second partitions 331 and 333. In addition, an intermediate dummy pattern 314b may be further provided on the auxiliary electrode 312 between the first partition 331 and the second partition 333. The intermediate layer 313 and the intermediate dummy patterns 314a and 314b may be formed in the same process and may contain the same material. The intermediate layer 313 and the intermediate layer dummy patterns 314a and 314b may be separated from each other by first and second partitions 331 and 333 having a reverse taper shape. Accordingly, each of the first and second connection electrodes 315b and 315c may contact the auxiliary electrode 312 between the intermediate layer 313 and the intermediate dummy patterns 314a and 314b separated by the first and second partitions 331 and 333.

The pattern-defining layer 340 may include a first pattern-defining layer 341 provided on the bank 320 and a second pattern-defining layer 343 provided on the first partition 331. The first and second pattern-defining layers 341 and 343 may be formed in the same process. The first and second pattern-defining layers 341 and 343 may be separated by the first partition 331.

The second electrode patterns 315 (315a, 315b, 315c) may be formed over the entire surface of the substrate 10 through a common mask. The second electrode pattern 315 may be divided into a second electrode 315a provided on the intermediate layer 313, and first and second connection electrodes 315b and 315c that are in direct contact with the auxiliary electrode 312 by the pattern-defining layer 340. The second electrode 315a and the first and second connection electrodes 315b and 315c may be integrated around the pattern-defining layer 340.

The second electrode 315a provided on the intermediate layer 313 may constitute a light emitting area EA in an area overlapping with the first electrode 311. In addition, the second electrode 315a may be connected on the auxiliary electrode 312 to the second connection electrode 315c provided on the second partition 333 not provided with the pattern-defining layer 340, as shown in b5 of FIG. 6.

The first connection electrode 315b and the second connection electrode 315c may contact the auxiliary electrode 312. In addition, each of the first connection electrode 315b and the second connection electrode 315c is formed of a metal and thus exhibits excellent step coverage characteristics. Therefore, the first connection electrode 315b and the second connection electrode 315c are provided on the side surface of each of the first and second partitions 331 and 333 as well.

The first connection electrode 315b provided between the first pattern-defining layer 341 and the second pattern-defining layer 343 may be thick near the edges due to the first pattern-defining layer 341 and the second pattern-defining layer 343 during the deposition process, as shown in b1 and b2 in FIG. 6. Accordingly, the light emitting display device of the present disclosure can reduce the contact resistance at the first contact portion CT1 between the first connection electrode 315b and the auxiliary electrode 312. In addition, the second connection electrode 315c provided between the first partition 331 and the second partition 333 may be thick near the edge, as shown in b3 and b4 of FIG. 6, due to the second pattern-defining layer 343. Here, the second connection electrode 315c may be thick even in the b4 area of FIG. 6 on the side surface of the second partition 333 not provided with the pattern-defining layer 340 due to the pattern-defining layer 340. Accordingly, the light emitting display device of the present disclosure can reduce the contact resistance in the second contact portion CT2 between the second connection electrode 315c and the auxiliary electrode 312. Meanwhile, the side surface of the second partition 333 that is not adjacent to the first partition 331 is hardly affected by the pattern-defining layer 340, so that the second connection electrode 315c is relatively thin, as shown in b5 of FIG. 6. In b5 of FIG. 6, the second connection electrode 315c is in contact with the auxiliary electrode 312 and is connected to the adjacent second electrode 315a, thereby supplying the voltage from the auxiliary electrode 312 to the second electrode 315a.

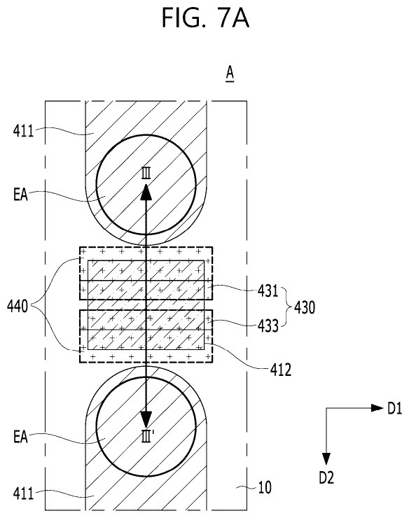

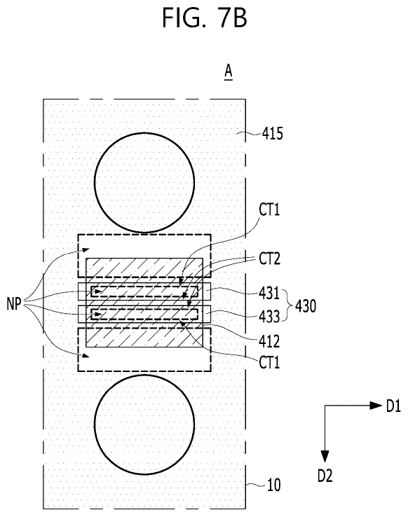

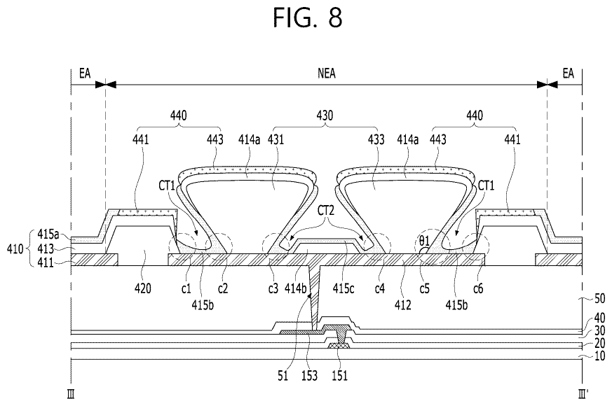

FIGS. 7A and 7B are enlarged views illustrating A in FIG. 2 according to a third embodiment. FIG. 7A schematically illustrates the area of the pattern-defining layer 440, and FIG. 7B schematically illustrates the area of the second electrode pattern 415 (415a, 415b, 415c). FIG. 8 is a cross-sectional view taken along line III-III′ of FIG. 7A.

With reference to FIGS. 7A and 7B, according to the third embodiment of the present disclosure, an auxiliary electrode 412 is provided in the non-light emitting area NEA, a first partition 431 and a second partition 433 overlapping the auxiliary electrode 412 are provided, a pattern-defining layer 440 is provided on the first partition 431 and the second partition 433, and second electrode patterns 415 (415a, 415b, 415c) are provided around the pattern-defining layer 440. In the light emitting display device according to the third embodiment of the present disclosure, the partition 430 and the pattern-defining layer 440 may be formed symmetrically between two adjacent light emitting areas EA.

Accordingly, the first partition 430 according to the third embodiment may include a first partition 431 and a second partition 433. The plane shape of the partition 430 according to the third embodiment may be the same as the partition 330 according to the second embodiment. As a result, the partition 430 according to the third embodiment has a length in the first direction D1 that is greater than a length in the first direction D1 of the light emitting area EA, thereby securing the contact area between the second electrode pattern 415 and the auxiliary electrode 412 corresponding to the length of the partition 430 in the first direction D1.

The pattern-defining layer 440 according to the third embodiment may include a first pattern-defining layer 441 provided from the first partition 431 to the area between the first electrode 411 and the auxiliary electrode 412, and a second pattern-defining layer 443 provided from the second partition 433 to the area between the first electrode 411 and the auxiliary electrode 412 corresponding to the other light emitting area EA.

The second electrode pattern 415 may be formed over the entire surface of the substrate 10 excluding an area partially overlapping the pattern-defining layer 430. In other words, the second electrode pattern 415 may be formed over the entire surface of the substrate 10 excluding the non-pattern area NP. For example, the non-pattern area NP may be provided in an area between the first partition 431 and the light emitting area EA and in an area where the first partition 431 is provided, and may be provided in the area between the second partition 433 and the light emitting area EA and in the area where the second partition 433 is provided.

As shown in FIG. 7B, the second electrode pattern 415 may have first and second contact portions CT1 and CT2 electrically connected to the auxiliary electrode 412 in the area where the second electrode pattern 415 overlaps the first and second partitions 431 and 433. The first contact portion CT1 may be an area where the second electrode pattern 415 is connected to the auxiliary electrode 412 at the edge of the first partition 431 and the edge of the second partition 433 that are not adjacent to each other. The second contact portion CT2 may be an area where the second electrode pattern 415 is connected to the auxiliary electrode 412 at the edge of the first partition 431 and the edge of the second partition 433 that are adjacent to each other.

With reference to FIG. 8, the light emitting display device according to the third embodiment of the present disclosure includes a light emitting element 410 including a first electrode 411, an intermediate layer 413, and a second electrode 415a in a light emitting area EA on a substrate 10, and includes an auxiliary electrode 412, a partition 430, a pattern-defining layer 440, a first connection electrode 415b, and a second connection electrode 415c in a non-light emitting area NEA. The bank 420 according to the third embodiment may cover the edge of the first electrode 411 and expose the auxiliary electrode 412. In addition, the bank 420 may cover the edge of the auxiliary electrode 412. As the bank 420 exposes the auxiliary electrode 412, the partition 430 may be provided directly on the auxiliary electrode 412.

The partition 430 according to the third embodiment may include a first partition 431 and a second partition 433. The partition 430 according to the third embodiment may be formed in a reverse taper shape. In addition, the side surfaces of the first and second partitions 331 and 333 may have an internal angle with respect to the substrate 10 of a first angle θ1. The first angle θ1 of the side surface of the first and second partitions 331 and 333 may be not less than 90° and less than 180°.

An intermediate layer 413 may be provided on the first electrode 411 and the bank 420, and an intermediate dummy pattern 414a may be provided on each of the first and second partitions 431 and 433. In addition, an intermediate dummy pattern 414b may be further provided on the auxiliary electrode 412 between the first partition 431 and the second partition 433. The intermediate layer 413 and the intermediate dummy patterns 414a and 414b may be separated from each other by the first and second partitions 431 and 433 having a reverse taper shape. Accordingly, each of the first and second connection electrodes 415b and 415c between the intermediate layer 413 and the intermediate dummy pattern 414a separated by the first and second partitions 431 and 433 and between the intermediate dummy patterns 414a and 414b may contact the auxiliary electrode 412.

The pattern-defining layer 440 according to the third embodiment may include a first pattern-defining layer 441 provided on the bank 420 and a second pattern-defining layer 443 provided on the first and second partitions 431 and 433. Because the light emitting display device according to the third embodiment of the present disclosure is provided with the second pattern-defining layer 443 on each of the first and second partitions 431 and 433, even if the second electrode pattern 415 is not directly deposited on the side surface of the first and second partitions 431 and 433, the second electrode pattern 415 may be provided on the side surface of the first and second partitions 431 and 433 by the pattern-defining layer 440.

The second electrode patterns 415 (415a, 415b, 415c) may be formed over the entire surface of the substrate 10 through a common mask. The second electrode pattern 415 may be divided into a second electrode 415a provided on the intermediate layer 413, and first and second connection electrodes 415b and 415c that are in direct contact with the auxiliary electrode 412 by the pattern-defining layer 440. The second electrode 415a and the first and second connection electrodes 415b and 415c may be integrated around the first and second pattern-defining layers 415b and 415c.

The first connection electrode 415b may be provided between the first partition 431 and the adjacent bank 420, and between the second partition 433 and the adjacent bank 420. Accordingly, the first connection electrode 415b contacts the auxiliary electrode 412 and is integrally connected to the second electrode 415a around the pattern-defining layer 440, thereby supplying a power voltage. In addition, the first connection electrode 415b may be provided on each side surface of the first partition 431 and the second partition 433 that are not adjacent to each other, but the present disclosure is not limited thereto.

The second connection electrode 415c may be provided between the first partition 431 and the second partition 433. The second connection electrode 415c may be in contact with the auxiliary electrode 412 exposed from the first and second partitions 431 and 433 between the first and second partitions 431 and 433. Accordingly, the second connection electrode 415c is in contact with the auxiliary electrode 412 and is integrally connected with the second electrode 415a around the pattern-defining layer 440, thereby supplying a power voltage. In addition, the second connection electrode 415c may be provided on each side surface of the first partition 431 and the second partition 433 adjacent to each other, but the present disclosure is not limited thereto.

The first and second connection electrodes 415b and 415c are formed by the pattern-defining layer 440 and may have thicker specific portions. As shown in c1, c2, c3, c4, c5, and c6 in FIG. 8, the first and second connection electrodes 415b and 415c may have thick portions near the edge between the bank 420 and the auxiliary electrode 412 and the edge between each partition 430 and the auxiliary electrode 412. Accordingly, the light emitting display device of the present disclosure can reduce the contact resistance in the first contact portion CT1 where the first connection electrode 415b contacts the auxiliary electrode 412 and in the second contact portion CT2 where the second connection electrode 415c contacts the auxiliary electrode 412.

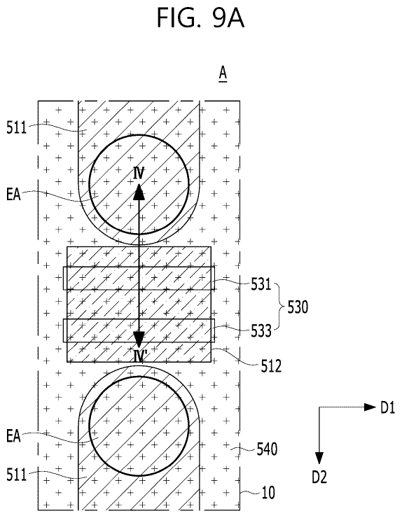

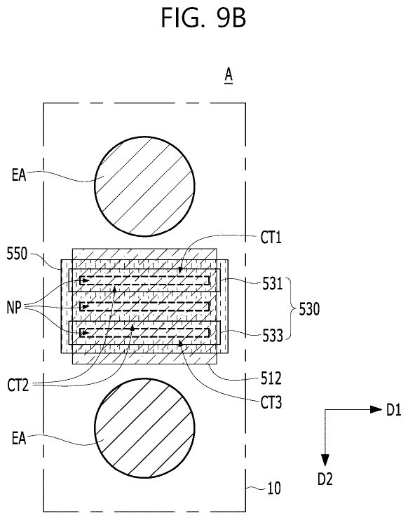

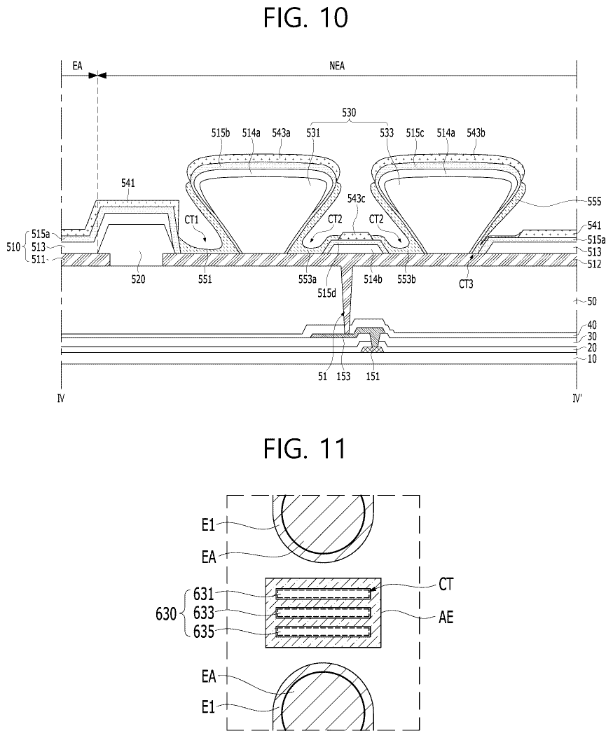

FIGS. 9A and 9B are enlarged views illustrating A in FIG. 2 according to a fourth embodiment. FIG. 9A schematically illustrates the area of the pattern-defining layer 540, and FIG. 9B schematically illustrates a connection electrode pattern 550. FIG. 10 is a cross-sectional view taken along line IV-IV′ of FIG. 9A.

With reference to FIGS. 9A and 9B, according to the fourth embodiment of the present disclosure, an auxiliary electrode 512 is provided in a non-light emitting area EA, a first partition 531 and a second partition 533 overlapping the auxiliary electrode 512 are provided, a pattern-defining layer 540 is provided over the entire surface of the substrate 10, and a connection electrode pattern 550 partially overlapping first and second partitions 531 and 533 is provided around the first and second partitions 531 and 533.

The partition 530 according to the fourth embodiment may include a first partition 531 and a second partition 533. The plane shape of the partition 530 according to the fourth embodiment may be the same as the partition 530 according to the third embodiment. As a result, the partition 530 according to the fourth embodiment has a length in the first direction D1 that is greater than a length in the first direction of the light emitting area EA, thereby securing the contact area between the second electrode pattern 515 and the auxiliary electrode 512 corresponding to the length of the partition 530 in the first direction D1.

The pattern-defining layer 540 (541, 543a, 543b, 543c) according to the fourth embodiment may be formed over the entire surface of the substrate 10. The pattern-defining layer 540 may cover the light emitting area EA and the non-light emitting area NEA and may be separated in some areas by the first and second partitions 531 and 533.

Meanwhile, although not shown in FIGS. 9A and 9B, the second electrode pattern 515 (515a, 515b, 515c, 515d) may be provided entirely on the substrate 10 such that it overlaps the pattern-defining layer 540. In addition, the second electrode pattern 515 may be separated in some areas by the first and second partitions 531 and 533.

The display device of the present disclosure according to the fourth embodiment may include connection electrode patterns 550 (551, 553a, 553b, 555) that contact the second electrode pattern 515 and the auxiliary electrode 512. The connection electrode pattern 550 may include a non-pattern area NP in which a pattern is not formed by the pattern-defining layer 540. The non-pattern area NP of the connection electrode pattern 550 may overlap with the first and second partitions 531 and 533.

The connection electrode pattern 550 may have first to third contact portions CT1, CT2, and CT3 electrically connected to the auxiliary electrode 512. The first contact portion CT1 may be an area where the connection electrode pattern 550 is connected to the auxiliary electrode 512 at the edge of the first partition 531 that is not adjacent to the second partition 533. The second contact portion CT2 may be an area where the connection electrode pattern 550 is connected to the auxiliary electrode 512 at the edge of the first partition 531 and the edge of the second partition 533 adjacent to each other. The third contact portion CT3 may be an area where the connection electrode pattern 550 is connected to the auxiliary electrode 512 at the edge of the second partition 533 that is not adjacent to the first partition 531.

With reference to FIG. 10, the light emitting display device according to the fourth embodiment of the present disclosure includes a light emitting element 510 including a first electrode 511, an intermediate layer 513, and a second electrode 515a in a light emitting area EA on a substrate 10, may include an auxiliary electrode 512, a partition 530, second electrode dummy patterns 515b and 515c, a first connection electrode 551, a second connection electrode 553a, a third connection electrode 553b, and a fourth connection electrode 555 in a non-light emitting area NEA, and may include a pattern-defining layer 540 (541, 543a, 543b, 543c) over the entire surface of the substrate 10.

The bank 520 according to the fourth embodiment may cover the edge of the first electrode 511 and expose the auxiliary electrode 512. In addition, the bank 520 may cover the edge of the auxiliary electrode 512. As the bank 520 exposes the auxiliary electrode 512, the partition 530 may be provided directly on the auxiliary electrode 512.

The partition 530 according to the fourth embodiment may include a first partition 531 and a second partition 533. The partition 530 according to the fourth embodiment may be formed in a reverse taper shape. In addition, the side surfaces of the first and second partitions 531 and 533 may have an internal angle with respect to the substrate 10 of a first angle θ1. The first angle 01 of the side surface of the first and second partitions 531 and 533 may be not less than 90° and less than 180°.

An intermediate layer 513 may be provided on the first electrode 511 and the bank 520, and an intermediate dummy pattern 514a may be provided on each of the first and second partitions 531 and 533. In addition, an intermediate dummy pattern 514b may be further provided on the auxiliary electrode 512 between the first partition 531 and the second partition 533. The intermediate layer 513 and the intermediate dummy patterns 514a and 514b may be separated from each other by first and second partitions 531 and 533 having a reverse taper shape. Accordingly, each of the first and second connection electrodes 551 and 553a between the intermediate layer 513 and the intermediate dummy pattern 514a separated by the first and second partitions 531 and 533 and between the intermediate dummy patterns 514a and 514b may contact the auxiliary electrode 512.

The second electrode patterns 515 (515a, 515b, 515c, 515d) according to the fourth embodiment may be provided over the entire surface of the substrate 10 and may be provided on the intermediate layer 513 and the intermediate dummy patterns 514a and 514b. The second electrode pattern 515 may be separated in some areas by the first and second partitions 531 and 533. Accordingly, the second electrode pattern 515 may include a second electrode 515a provided on the intermediate layer 513, second electrode patterns 515b and 515c provided on the intermediate dummy pattern 514a provided on each of the first and second partitions 531 and 533, and a second electrode pattern 515d provided on the intermediate dummy pattern 514b between the first and second partitions 531 and 533. The second electrode pattern 515 formed of a metal with excellent step coverage characteristics may be provided over a larger area than the intermediate layer 513 and the intermediate dummy patterns 514a and 514b. Therefore, the second electrode 515a may be provided from the light emitting area EA to the side surface of the bank 520, the second electrode dummy patterns 515b and 515c may be provided on the side surface of each of the first and second partitions 531 and 533, and the second electrode dummy pattern 515d may cover the surface of the intermediate dummy pattern 514b. However, the second electrode 515a and the second electrode dummy patterns 515b, 515c, and 515d formed on the side surface may be thinner than those formed on the surface perpendicular to the deposition direction, so that their contact resistance with the auxiliary electrode 512 may be high. Alternatively, the second electrode dummy patterns 515b and 515c may not be in contact with the auxiliary electrode 512 because they are not evenly deposited on the side surface of the partition 530 due to various factors.

The pattern-defining layer 540 (541, 543a, 543b, and 543c) according to the fourth embodiment may be provided over the entire surface of the substrate 10. The pattern-defining layer 540 may be separated in some areas by the first and second partitions 531 and 533. Accordingly, the pattern-defining layer 540 includes a first pattern-defining layer 541 provided on the second electrode 515a, second and third pattern-defining layers provided on the first and second partitions 531 and 533, and a fourth pattern-defining layer 543c provided on the second electrode pattern 515d between the first and second partitions 531 and 533. The pattern-defining layer 540 is formed of an organic material and thus exhibit lower step coverage characteristics compared to a metal. Therefore, the pattern-defining layer 540 may expose the second electrode pattern 515 (515a, 515b, 515c, 515d) provided on the side surface of the bank 520 or the side surface of the first and second partitions 531 and 533 during the deposition process. In addition, the pattern-defining layer 540 according to the fourth embodiment is formed over the entire surface of the substrate 10 and thus formation thereof through a common mask is possible without a separate mask. Therefore, the present disclosure according to the fourth embodiment may reduce the number of masks in manufacturing.

The present disclosure according to the fourth embodiment may include a connection electrode pattern 550 (551, 553a, 553b, 555), separate from the second electrode pattern 515. The connection electrode pattern 550 may include a first connection electrode 551 contacting the auxiliary electrode 512 at the edge of the first partition 531 that is not adjacent to the second partition 533, second and third connection electrodes 553a and 553b that contact the auxiliary electrode 512 at the edge of the first partition 531 and the second partition 533 adjacent to each other, and a fourth connection electrode 555 that contacts the auxiliary electrode 512 at the edge of the second partition 533 that is not adjacent to the first partition 531. Here, the second and third connection electrodes 553a and 553b may be integrated around the fourth pattern-defining layer 543c.

The present disclosure includes a first contact portion CT1 through which the first connection electrode 551 and the auxiliary electrode 512 are connected to each other, a second contact portion CT2 through which the second and third connection electrodes 553a and 553b and the auxiliary electrode 512 are connected to each other, and a third contact portion CT3 through which the fourth connection electrode 555 and the auxiliary electrode 512 are connected to each other. In the first contact portion CT1, the first connection electrode 551 may contact the second electrode 515a and the auxiliary electrode 512 to electrically connect the second electrode 515a to the auxiliary electrode 512, and may contact the second electrode pattern 515b provided on the side surface of the first partition 531. In the second contact portion CT2, the second connection electrode 553a may contact the auxiliary electrode 512 and the second electrode pattern 515b provided with the side surface of the first partition 531, and the third connection electrode 553b may contact the auxiliary electrode 512 and the second electrode pattern 515c provided on the side surface of the second partition 533. At the same time, the second and third connection electrodes 553a and 553b contact the second electrode pattern 515d to electrically connect the auxiliary electrode 512 to the second electrode patterns 515b, 515c, and 515d. In the third contact portion CT3, the fourth connection electrode 555 may contact the auxiliary electrode 512 and the second electrode pattern 515c provided on the side surface of the second partition 533, and contact the second electrode 515a extending to the adjacent light emitting area EA. Therefore, the fourth connection electrode 555 may electrically connect the second electrode pattern 515c and the auxiliary electrode 512 to the second electrode 515a. Accordingly, the connection electrode patterns 550 (551, 553a, 553b, 555) according to the fourth embodiment connect the second electrode patterns (515; 515a, 515b, 515c, 515d) separated by the partition 530 to each other, thereby supplying the power voltage from the auxiliary electrode 512 to the adjacent light emitting element 510, so that the power voltage can flow uniformly across the entire surface of the substrate 10.

The first to fourth connection electrodes 551, 553a, 553b, and 555 may be formed by the first to fourth pattern-defining layers 541, 543a, 543b, and 543c without a mask. The first to fourth connection electrodes 551, 553a, 553b, and 555 cannot be adhered to the pattern-defining layer 540 due to the low affinity for the pattern-defining layer 540 during the deposition process, one or more of the first to fourth connection electrodes evaporate and the remaining connection electrodes flow down. Accordingly, the first to fourth connection electrodes 551, 553a, 553b, and 555 may be thick compared to those formed on the side surfaces of the bank 520 and the partition 530 in the first to third contact portions CT1, CT2, and CT3. Thus, the light emitting display device of the present disclosure can reduce contact resistance in the first to third contact portions CT1, CT2, and CT3. For this purpose, the connection electrode pattern 550 may be formed of a conductive material.

FIGS. 11 to 13 are plan views illustrating various types of partitions 630, 730, and 830.

With reference to FIG. 11, the partition 630 may include first to third partitions 631, 633, and 635 that overlap the auxiliary electrode AE. The first to third partitions 631, 633, and 635 may be arranged in one direction and spaced apart from each other. In addition, the first to third partitions 631, 633, and 635 may have a contact portion CT where the auxiliary electrode AE and the connection electrode or the second electrode pattern contact at each edge thereof. Meanwhile, the partition 630 may have a reverse taper shape when viewed from the cross-section. As the light emitting display device of the present disclosure includes a plurality of partitions 630, the contact area between the auxiliary electrode AE and the connection electrode or second electrode pattern can be increased.

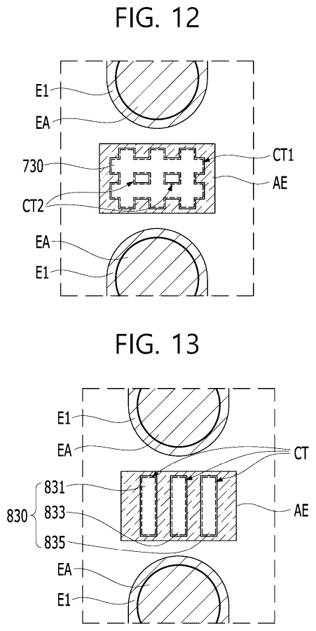

With reference to FIG. 12, the partition 730 may be formed in a cross shape. For example, the partition 730 has a structure in which the edges of a cross-shape are connected to each other, and a plurality of partitions provided in a first direction are integrated with a plurality of partitions provided in a second direction intersecting the first direction. This cross-shaped partition 730 enables the auxiliary electrode AE to contact the connection electrode or the second electrode pattern at the first contact portion CT1 along the outer edge line and the second contact portion CT2 along the inner edge line. Meanwhile, the partition 730 may have a reverse taper shape when viewed in cross section. In the light emitting display device of the present disclosure, the partition 730 is formed in a cross shape, thereby increasing the contact area between the auxiliary electrode AE and the connection electrode or the second electrode pattern by the edge of the partitions intersecting in different directions.

With reference to FIG. 13, the partition 830 may include first to third partitions 831, 833, and 835 that overlap the auxiliary electrode AE. The first to third partitions 831, 833, and 835 may be spaced apart from each other in a direction to connect adjacent first electrodes E1. In addition, the first to third partitions 831, 833, and 835 may have contact portions CT where the auxiliary electrode AE and the connection electrode or second electrode pattern are in contact at each edge thereof. Meanwhile, the partition 830 may have a reverse taper shape when viewed from the cross-section. As the light emitting display device of the present disclosure includes a plurality of partitions 830, the contact area between the auxiliary electrode AE and the connection electrode or second electrode pattern can be increased.

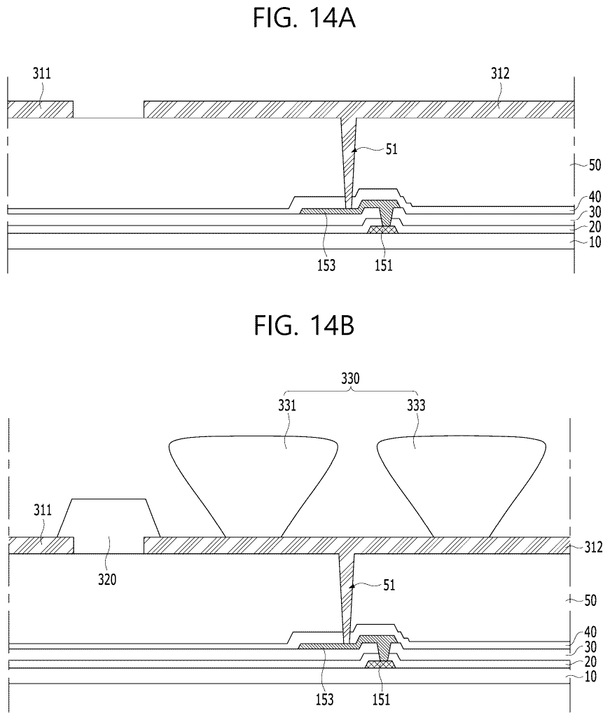

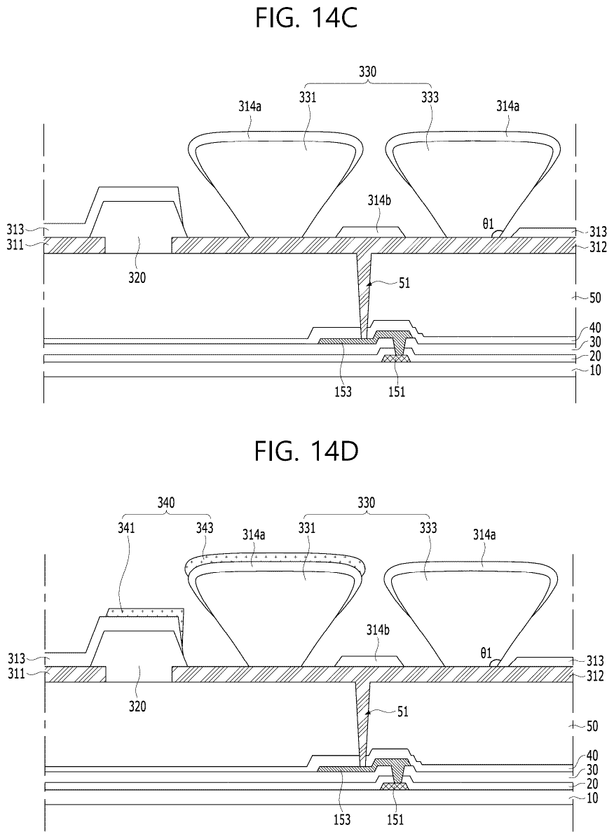

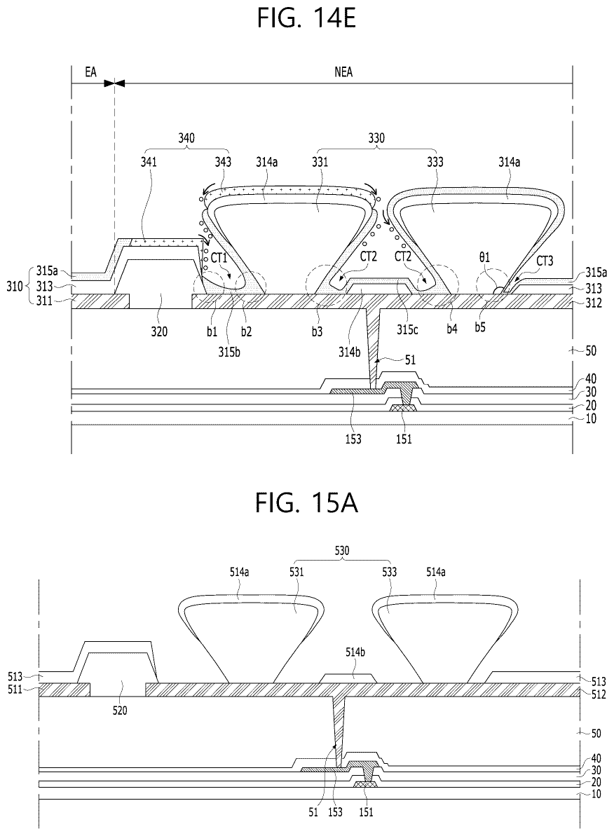

FIGS. 14A to 14E are cross-sectional views illustrating the process according to the second embodiment.

With reference to FIG. 14A, a first auxiliary line 151 is formed in the same layer as the light-blocking layer (110 in FIG. 4) on the substrate 10 through a mask process, and a buffer film 20 and an interlayer insulating film 30 may be formed sequentially on the substrate 10 on which the first auxiliary line 151 is formed. A second auxiliary line 153 is formed in the same layer as the source electrode (141 in FIG. 4) and the drain electrode (143 in FIG. 4) on the substrate 10 including the interlayer insulating film 30 through a mask process. A passivation layer 40 and a planarization layer 50 may be formed on the substrate 10 including the second auxiliary line 153. Here, a contact hole 51 may be formed in the passivation layer 40 and the planarization layer 50. A first electrode 311 and an auxiliary electrode 312 may be formed through a mask process on the substrate 10 including the planarization layer 50 such that it is spaced apart from each other.

Next, with reference to FIG. 14B, a bank 320 and a partition 330 may be formed sequentially. The bank 320 covers the edge of the first electrode 311 and the edge of the auxiliary electrode 312, and is formed through a mask process to partially expose the surfaces of the first electrode 311 and the auxiliary electrode 312. The partition 330 may be formed in the same layer as the spacer (S in FIG. 2) on the bank 320. The partition 330 may be formed of a first partition 331 and a second partition 333 spaced apart from each other on the auxiliary electrode 312 through a mask process. Here, each of the first and second partitions 331 and 333 may be formed in a reverse taper shape so that the top surface has a larger area than the bottom surface.

Next, with reference to FIG. 14C, an intermediate layer material may be deposited over the entire surface of the substrate 10 on the banks 320 and the partitions 330. Here, the intermediate layer material is divided by the first and second partitions 331 and 333 to form an intermediate layer 313 on the first electrode 311 and the bank 320, an intermediate dummy pattern 314a on each of the first and second partitions 331 and 333, and an intermediate dummy pattern 314b between the first and second partitions 331 and 333.

With reference to FIG. 14D, a pattern-defining layer 340 may be formed on the intermediate layer 313 and the intermediate dummy pattern 314a formed on the bank 320 and the first partition 331, respectively, through a mask process. Here, through the first partition 331, the pattern-defining layer 340 is separated into a first pattern-defining layer 341 on the bank 320 and a second pattern-defining layer 343 on the first partition 331.

Next, with reference to FIG. 14E, a second electrode material may be formed over the entire surface of the substrate 10 including the pattern-defining layer 340. The second electrode material may be not adhered to the surface of the pattern-defining layer 340 due to very low affinity thereof for the pattern-defining layer 340. Some of the second electrode material removed from the pattern-defining layer 340 may flow into a low location. The second electrode material may be formed into a second electrode 315a, a first connection electrode 315b, and a second connection electrode 315c by the pattern-defining layer 340. At this time, the first connection electrode 315b is affected by the first pattern-defining layer 341 formed on the top and side surfaces of the bank 320 and the second pattern-defining layer 343 formed on the first partition 331. As a result, the first connection electrode 315b may have a thick first contact portion CT1 near the edge thereof, as shown in b1 and b2 of FIG. 14E. In addition, the second connection electrode 315c is affected by the second pattern-defining layer 343 formed on the first partition 331 and the second electrode material is injected along each adjacent side surface of the first partition 331 and the second partition 333. As a result, the second connection electrode 315c has a thick second contact portion CT2 near the edge thereof, as shown in b3 and b4 of FIG. 14E. Meanwhile, the second electrode 315a and the first and second connection electrodes 315b and 315c may be integrated around the pattern-defining layer 340. Meanwhile, the second electrode material is formed of a metal with excellent step coverage and thus may be deposited on the side surface of the second partition 333 not provided with the pattern-defining layer 340 by appropriately adjusting the first angle θ1 on the side surface of the partition 330. Accordingly, the second connection electrode 315c and the second electrode 315a extending from the light emitting area EA adjacent to the second partition 333 may be connected to each other. As such, the light emitting display device of the present disclosure is provided with the pattern-defining layer 340 and the partition 330, thereby reducing the contact resistance between the auxiliary electrode 312 and the connection electrodes 315b and 315c and uniformly supplying a power voltage throughout the substrate 10.

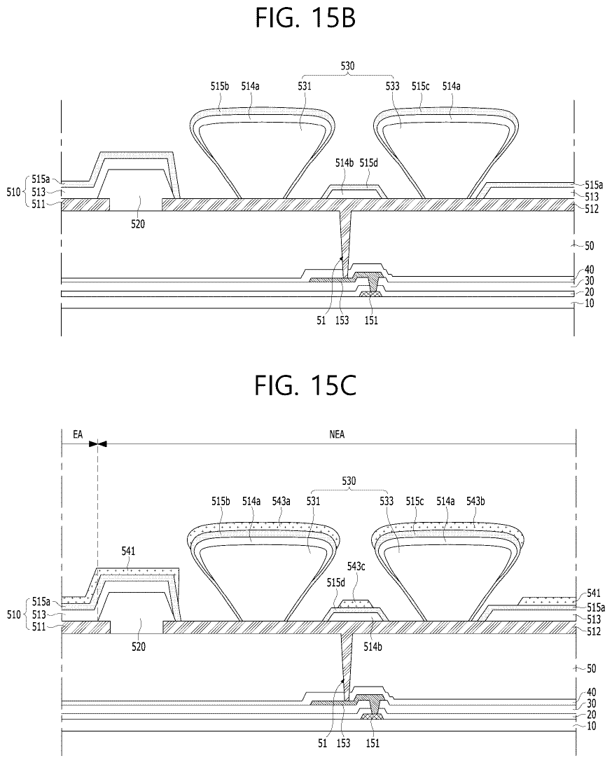

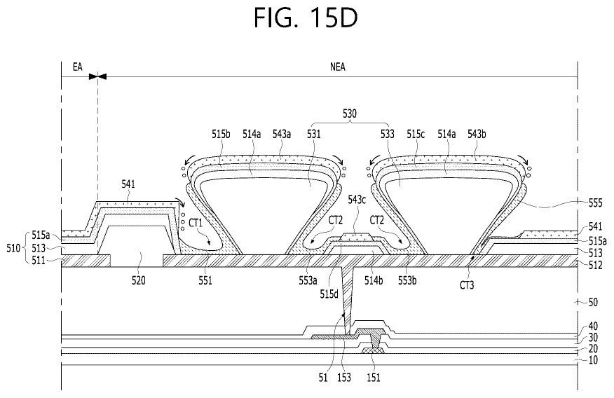

FIGS. 15A to 15D are cross-sectional views illustrating the process according to the fourth embodiment.

With reference to FIG. 15A, a first auxiliary line 151, a second auxiliary line 153, a buffer film 20, an interlayer insulating film 30, a passivation layer 40, a planarization layer 50, a first electrode 511, an auxiliary electrode 512, a bank 520, a partition 530, an intermediate layer 513, and an intermediate dummy patterns 514a and 514b may be formed on a substrate 10. The process for this structure may be the same as in FIGS. 14A to 14C.

Next, with reference to FIG. 15B, a second electrode material may be formed over the entire surface of the substrate 10. The second electrode material is separated by the first and second partitions 531 and 533 to form a second electrode 515a on the intermediate layer 513, second electrode dummy patterns 515b and 515c on the first and second partitions 531 and 533, and a second electrode dummy pattern 515d between the first and second partitions 531 and 533. The second electrode 515a and the second electrode dummy patterns 515b, 515c, and 515d are formed of a metal with excellent step coverage and may also be formed on the side surface of the bank 520 or the side surface of the partition 530 and come into contact with the auxiliary electrode 512. However, the second electrode 515a and the second electrode dummy patterns 515b, 515c, and 515d formed on the side surface may be thinner than those formed on the surface perpendicular to the deposition direction, so that the contact resistance with the auxiliary electrode 512 may be high. Alternatively, the second electrode dummy patterns 515b and 515c may not be in contact with the auxiliary electrode 512 because they are not evenly deposited on the side surface of the partition 530 due to various factors.

Next, with reference to FIG. 15C, a pattern-defining layer 540 (541, 543a, 543b, 543c) may be formed over the entire surface of the substrate 10 including the second electrode patterns 515 (515a, 515b, 515c, 515d). The pattern-defining layer 540 is formed of an organic material, thereby reducing step coverage characteristics compared to a metal. Accordingly, the pattern-defining layer 540 may expose the second electrode pattern 515 (515a, 515b, 515c, 515d) provided on the side surface of the bank 520 or the side surface of the first and second partitions 531 and 533 during the deposition process. The pattern-defining layer 540 is divided by the first and second partitions 531 and 533, into a first pattern-defining layer 541 on the second electrode 515a, a second pattern-defining layer 543a on the first partition 531, a third pattern-defining layer 543b on the second partition 533, and a fourth pattern-defining layer 543c between the first and second partitions 531 and 533.

Next, with reference to FIG. 15D, connection electrode patterns 550 (551, 553a, 553b, 555) may be formed on the substrate 10 including the pattern-defining layer 540. The connection electrode pattern 550 is formed of a conductive material and may be formed into a space where the pattern-defining layer 540 is not provided due to low affinity for the pattern-defining layer 540. The connection electrode pattern 550 includes a first connection electrode 551 between the first and second pattern-defining layers 541 and 543a, a second connection electrode 553a between the second and fourth pattern-defining layers 543a and 543c, a third connection electrode 553b between the third and fourth pattern-defining layers 543b and 543c, and a fourth connection electrode 555 between the third pattern-definition layer 543b and the first pattern-defining layer extending from the light emitting area EA adjacent thereto. Here, the second and third connection electrodes 553a and 553b may be formed integrally. Accordingly, the first to fourth connection electrodes 551, 553a, 553b, and 555 connect the second electrode 515a and the second electrode dummy patterns 515b, 515c, and 515d to each other, and contact the auxiliary electrode 512 at the first to third contact portions CT1, CT2, and CT3 to supply a power voltage to the light emitting element 510. In addition, the first to fourth connection electrodes 551, 553a, 553b, and 555 may be relatively thick in the first to third contact portions CT1, CT2, and CT3, thereby reducing the contact resistance between the auxiliary electrode 512 and the second electrode patterns 515 (515a, 515b, 515c, and 515d) and more uniformly supplying power voltage to the entire substrate 10.

In addition, in the light emitting display device of the present disclosure according to the fourth embodiment, all of the second electrode pattern 515, the pattern-defining layer 540, and the connection electrode pattern 550 may be formed using a common mask. The light emitting display device according to the fourth embodiment of the present disclosure has a partition 530 having a reverse taper shape on the auxiliary electrode 512 and includes a pattern-defining layer 540 formed on the entire surface, thereby eliminating the necessity of a separate mask for patterning the components for forming the bank 520 and the partition 530. Accordingly, the light emitting display device according to the fourth embodiment of the present disclosure can have the effect of reducing the number of masks.

A light emitting device according to one embodiment of the present disclosure may include a plurality of sub-pixels the each have a light emitting area. The light emitting device may comprise a substrate, a first electrode at each light emitting area on the substrate, an intermediate layer and a second electrode on the first electrode, an auxiliary electrode at a non-light emitting area and spaced apart from the first electrode on the substrate, a bank exposing the light emitting area and the auxiliary electrode, a first partition on the auxiliary electrode configured to expose a portion of the auxiliary electrode, a first pattern-defining layer on the first partition and a connection electrode on the auxiliary electrode and electrically connected to the second electrode.

In a light emitting device according to one embodiment of the present disclosure, the second electrode may be at the light emitting area and a side surface of the bank. The second electrode may be integral with the connection electrode.

In a light emitting device according to one embodiment of the present disclosure, the connection electrode may extend from the auxiliary electrode and may be on a side surface of the first partition.

In a light emitting device according to one embodiment of the present disclosure, a thickness of the connection electrode near an edge between the auxiliary electrode and the first partition may be greater than a thickness of the connection electrode on a side surface of the first partition adjacent to the first pattern-defining layer.

A light emitting device according to one embodiment of the present disclosure may further comprise a second pattern-defining layer on a top surface of the bank and in a same layer as the first pattern-defining layer.

In a light emitting device according to one embodiment of the present disclosure, a length in a first direction of an area where the auxiliary electrode contacts the connection electrode may be greater than a length along the first direction of the light emitting area.

In a light emitting device according to one embodiment of the present disclosure, the first partition may comprise a bottom surface contacting the auxiliary electrode and a top surface opposite to the bottom surface. A length in the first direction of the bottom surface of may be smaller than a length of the auxiliary electrode along the first direction, and a length in the first direction of the top surface may be greater than the length along the first direction of the auxiliary electrode.

In a light emitting device according to one embodiment of the present disclosure, the first partition may comprise a plurality of first partitions. The plurality of first partitions may be spaced apart from each other on the auxiliary electrode.

In a light emitting device according to one embodiment of the present disclosure, the connection electrode may contact the auxiliary electrode among the plurality of first partitions.

In a light emitting device according to one embodiment of the present disclosure, the first partition may comprise a cross shape in a plan view.

In a light emitting device according to one embodiment of the present disclosure, the connection electrode may be in contact with the auxiliary electrode along an intersecting edge of the first partition.

A light emitting device according to one embodiment of the present disclosure may further comprise a spacer on the bank. The first partition may be formed of the same material as the spacer.

A light emitting device according to one embodiment of the present disclosure may further comprise an intermediate dummy pattern between the first partition and the first pattern-defining layer. The intermediate dummy patter may be in a same layer as the intermediate layer. The connection electrode may contact the auxiliary electrode between the intermediate layer and the intermediate dummy pattern.

In a light emitting device according to one embodiment of the present disclosure, the first pattern-defining layer may comprise a polycyclic aromatic compound.

A light emitting device according to one embodiment of the present disclosure may include a plurality of sub-pixels that each have a light emitting area. The light emitting display device may comprise a substrate, a first electrode at each light emitting area on the substrate, an auxiliary electrode at a non-light emitting area and spaced apart from the first electrode on the substrate, a bank exposing the light emitting area and the auxiliary electrode, a first partition spaced from the bank and on the auxiliary electrode, a second electrode on the first electrode and the bank, a second electrode dummy pattern in a same layer as the second electrode and on the first partition, a pattern-defining layer on the bank and on the first partition to be in a same layer as the second electrode and the second electrode dummy pattern, and a connection electrode contacting each of the second electrode, the second electrode dummy pattern at a portion exposed from the pattern-defining layer, and the auxiliary electrode.

A light emitting device according to one embodiment of the present disclosure may further comprise an intermediate layer between the first electrode and the second electrode; and an intermediate dummy pattern between the first partition and the first pattern-defining layer. The connection electrode may contact the auxiliary electrode between the intermediate layer and the intermediate dummy pattern.

In a light emitting device according to one embodiment of the present disclosure, the pattern-defining layer may expose the second electrode on a side surface of the bank and the second electrode dummy pattern on a side surface of the first partition.

In a light emitting device according to one embodiment of the present disclosure, the first partition may have a decreasing width toward the substrate.

In a light emitting device according to one embodiment of the present disclosure, the first partition may comprise a plurality of first partitions.

A light emitting device according to one embodiment of the present disclosure may further comprise a second partition intersecting the first partition.

In a light emitting device according to one embodiment of the present disclosure, the pattern-defining layer may comprise a polycyclic aromatic compound.

In a light emitting device according to one embodiment of the present disclosure, the pattern-defining layer may comprise a material having a low affinity for a conductive material.

As apparent from the foregoing, the light emitting display device of the present disclosure may have the following effects.

First, the light emitting display device according to the present disclosure includes a reverse taper-shaped patrtion on the auxiliary electrode, thus providing an effect of disconnecting the material of the intermediate layer, and includes a connection electrode between the disconnected intermediate layer and the intermediate dummy pattern through the pattern-defining layer, thus providing effects of lowering the contact resistance between the auxiliary electrode and the second electrode, uniformly supplying current to the entire display area, and uniformizing the luminance within the display area.

Second, the light emitting display device according to the present disclosure includes a connection electrode formed through a pattern-defining layer to make the connection electrode relatively thick near the edge between the auxiliary electrode, and the bank and the barrier, thus providing an effect of reducing the contact resistance.

Third, the light emitting display device according to the present disclosure enables simultaneous formation of the second electrode and the connection electrode through the patterned pattern-defining layer, thus providing an effect of easily forming the connection electrode.

Fourth, the light emitting display device according to the present disclosure enables formation of connection electrodes with the pattern-defining layer through a common mask, thus having an effect of minimizing, or at least reducing, the number of masks.

Fifth, the light emitting display device according to the present disclosure enables formation of connection electrodes using the pattern-defining layer, thus providing effects of reducing the number of masks, uniformizing luminance through contact between the second electrode and auxiliary electrode, and reducing production energy and power consumption. Accordingly, the light emitting display device of the present disclosure has an ESG (environmental/social/governance) effect in terms of environmental friendliness and process optimization.

The effects of the present disclosure are not limited to those mentioned above and other effects not mentioned will be clearly understood by those skilled in the art from the description above.

It will be apparent to those skilled in the art that various modifications and variations can be made in the light emitting display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A light emitting display device including a plurality of sub-pixels that each have a light emitting area, the light emitting display device comprising:
a substrate;
a first electrode at each light emitting area on the substrate;
an intermediate layer and a second electrode on the first electrode;
an auxiliary electrode at a non-light emitting area and spaced apart from the first electrode on the substrate;
a bank exposing the light emitting area and the auxiliary electrode;
a first partition on the auxiliary electrode and configured to expose a portion of the auxiliary electrode;
a first pattern-defining layer on the first partition; and
a connection electrode on the auxiliary electrode and electrically connected to the second electrode.

2. The light emitting display device according to claim 1, wherein the second electrode is at the light emitting area and a side surface of the bank, and wherein the second electrode is integral with the connection electrode.

3. The light emitting display device according to claim 2, wherein the connection electrode extends from the auxiliary electrode and is on a side surface of the first partition.

4. The light emitting display device according to claim 3, wherein a thickness of the connection electrode near an edge between the auxiliary electrode and the first partition is greater than a thickness of the connection electrode on a side surface of the first partition adjacent to the first pattern-defining layer.

5. The light emitting display device according to claim 2, further comprising a second pattern-defining layer on a top surface of the bank and in a same layer as the first pattern-defining layer.

6. The light emitting display device according to claim 1, wherein the first partition comprises a plurality of first partitions, and
wherein the plurality of first partitions are spaced apart from each other on the auxiliary electrode.

7. The light emitting display device according to claim 6, wherein the connection electrode contacts the auxiliary electrode among the plurality of first partitions.

8. The light emitting display device according to claim 1, wherein the first partition comprises a cross shape in a plan view.

9. The light emitting display device according to claim 8, wherein the connection electrode is in contact with the auxiliary electrode along an intersecting edge of the first partition.

10. The light emitting display device according to claim 1, further comprising a spacer on the bank, wherein the first partition is formed of the same material as the spacer.

11. The light emitting display device according to claim 1, further comprising an intermediate dummy pattern between the first partition and the first pattern-defining layer,
wherein the intermediate dummy pattern is in a same layer as the intermediate layer, and
wherein the connection electrode contacts the auxiliary electrode between the intermediate layer and the intermediate dummy pattern.

12. The light emitting display device according to claim 1, wherein the first pattern-defining layer comprises a polycyclic aromatic compound.

13. A light emitting display device including a plurality of sub-pixels that each have a light emitting area, the light emitting display device comprising:
a substrate;
a first electrode at each light emitting area on the substrate;
an auxiliary electrode at a non-light emitting area and spaced apart from the first electrode on the substrate;
a bank exposing the light emitting area and the auxiliary electrode;
a first partition spaced from the bank and on the auxiliary electrode;
a second electrode on the first electrode and the bank;
a second electrode dummy pattern in a same layer as the second electrode and on the first partition;
a pattern-defining layer on the bank and on the first partition to be in a same layer as the second electrode and the second electrode dummy pattern; and
a connection electrode contacting each of the second electrode, the second electrode dummy pattern at a portion exposed from the pattern-defining layer, and the auxiliary electrode.

14. The light emitting display device according to claim 13, further comprising:
an intermediate layer between the first electrode and the second electrode; and
an intermediate dummy pattern between the first partition and the pattern-defining layer,
wherein the connection electrode contacts the auxiliary electrode between the intermediate layer and the intermediate dummy pattern.

15. The light emitting display device according to claim 13, wherein the pattern-defining layer exposes the second electrode on a side surface of the bank and the second electrode dummy pattern on a side surface of the first partition.

16. The light emitting display device according to claim 13, wherein the first partition has a decreasing width toward the substrate.

17. The light emitting display device according to claim 13, wherein the first partition comprises a plurality of first partitions.

18. The light emitting display device according to claim 13, further comprising a second partition intersecting the first partition.

19. The light emitting display device according to claim 13, wherein the pattern-defining layer comprises a polycyclic aromatic compound.

20. The light emitting display device according to claim 13, wherein the pattern defining layer comprises a material having a low affinity for a conductive material.
